(19) United States
(12) Patent Application Publication
(10) Pub. No.: US 2025/0392096 A1
(43) Pub. Date: Dec. 25, 2025

(54) SUBSTRATE, ELECTRONIC DEVICE, ELECTRONIC MODULE, AND MODULE DEVICE

(71) Applicant: KYOCERA Corporation, Kyoto-shi, Kyoto (JP)

(72) Inventors: Kouichirou SUGAI, Kyoto-shi (JP); Kyota SHIMADA, Kyoto-shi (JP)

(73) Assignee: KYOCERA Corporation, Kyoto-shi, Kyoto (JP)

(21) Appl. No.: 18/879,110

(22) PCT Filed: Jul. 5, 2023
(86) PCT No.: PCT/JP2023/024868

§ 371 Date: Dec. 26, 2024

(30) Foreign Application Priority Data
Jul. 5, 2022 (JP) 2022-108631

(51) Int. Cl. H01S 5/02315

(52) U.S. Cl. CPC H01S 5/02315

(57) ABSTRACT

To increase the coefficient of thermal conductivity. A substrate includes a base including a first surface, a second surface located on an opposite side of the first surface, at least one first recessed portion opening to the first surface, and at least one second recessed portion opening to the second surface; a first metal member located inside the at least one first recessed portion; and a second metal member located inside the at least one second recessed portion, in which the coefficient of thermal conductivity of the first metal member and the coefficient of thermal conductivity of the second metal member are higher than the coefficient of thermal conductivity of the base.

### TECHNICAL FIELD

The present disclosure relates to a substrate on which an electronic element is mounted, and the like.

### BACKGROUND OF INVENTION

As disclosed in Patent Documents 1 and 2, a substrate on which an electronic element is mounted is known, the substrate having an increased coefficient of thermal conductivity to quickly dissipate heat generated from the electronic element.

### CITATION LIST

### Patent Literature

Patent Document 1: WO 2018/117232
Patent Document 2: WO 2011/059070

### SUMMARY

A substrate according to an aspect of the present disclosure includes a base including a first surface, a second surface located on an opposite side of the first surface, at least one first recessed portion opening to the first surface, and at least one second recessed portion opening to the second surface, a first metal member located inside the at least one first recessed portion, and a second metal member located inside the at least one second recessed portion, in which a coefficient of thermal conductivity of the first metal member and a coefficient of thermal conductivity of the second metal member are higher than a coefficient of thermal conductivity of the base.

### BRIEF DESCRIPTION OF THE DRAWINGS

FIG. 1 is a perspective view of a module device according to a first embodiment of the present disclosure.

FIG. 2 is a top view of the module device.

FIG. 3 is a cross-sectional view taken along an arrow line III-III in FIG. 2.

FIG. 4 is a top view of a substrate according to the first embodiment of the present disclosure.

FIG. 5 is a view of a substrate and an electronic element according to the first embodiment of the present disclosure viewed from a Y axis direction.

FIG. 6 is a top view of a substrate according to a second embodiment of the present disclosure.

FIG. 7 is a view of a substrate and an electronic element according to the second embodiment of the present disclosure viewed from the Y axis direction.

FIG. 8 is a top view of a substrate according to a third embodiment of the present disclosure.

FIG. 9 is a view of a substrate and an electronic element according to the third embodiment of the present disclosure viewed from the Y axis direction.

FIG. 10 is a top view of a substrate according to a fourth embodiment of the present disclosure.

FIG. 11 is a cross-sectional view taken along an arrow line XI-XI in FIG. 10.

FIG. 12 is a cross-sectional view taken along an arrow line XII-XII in FIG. 10.

FIG. 13 is a top view of a substrate according to a fifth embodiment of the present disclosure.

FIG. 14 is a view of a substrate and an electronic element according to the fifth embodiment of the present disclosure viewed from the Y axis direction.

### DESCRIPTION OF EMBODIMENTS

In a substrate on which a component such as an electronic element is mounted, a substrate having a further increased coefficient of thermal conductivity is desired.

According to an aspect of the present disclosure, the coefficient of thermal conductivity can be increased.

### First Embodiment

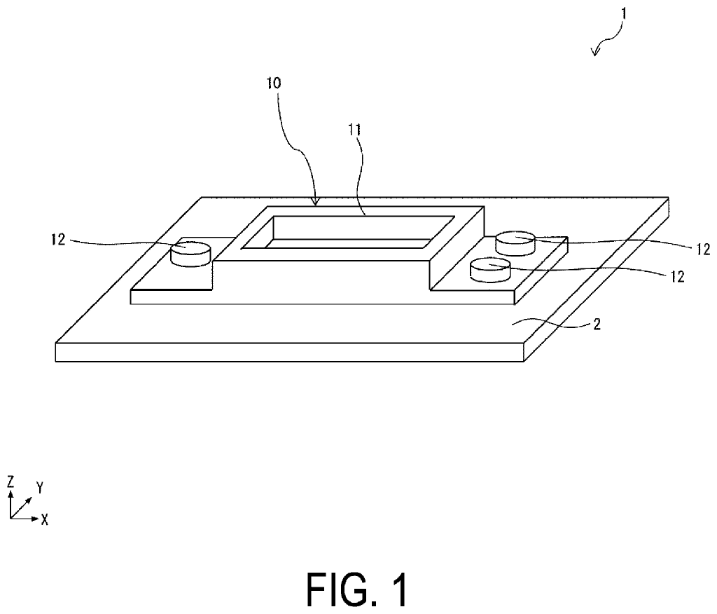

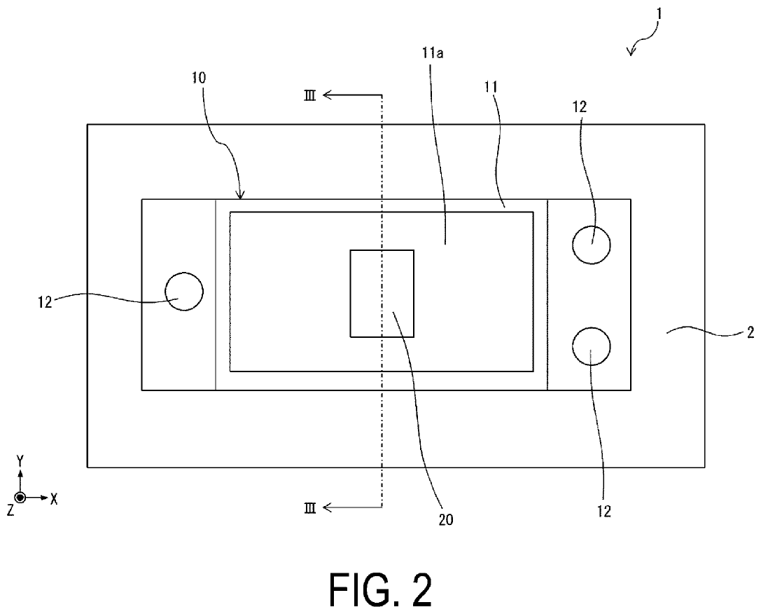

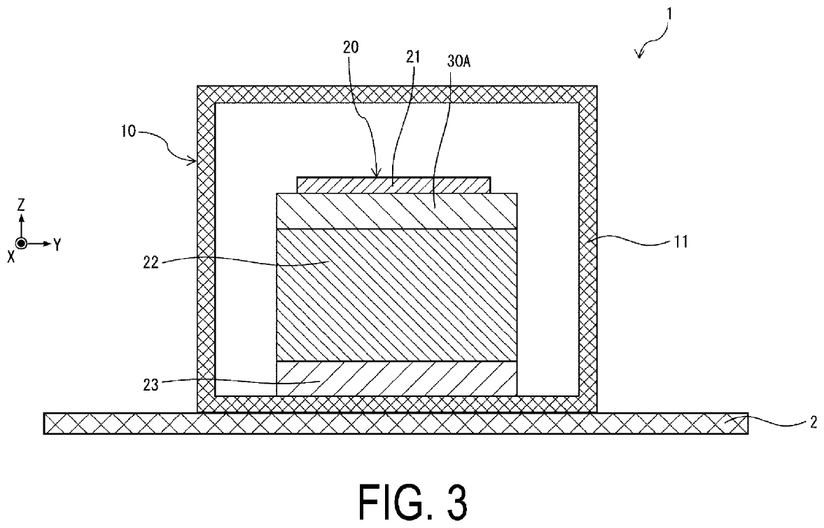

An embodiment of the present disclosure will be described in detail below. FIG. 1 is a perspective view of a module device 1 according to the present embodiment. FIG. 2 is a top view of the module device 1. In FIG. 2, for convenience of explanation, an upper surface of a case 11, which will be described later, is not illustrated. FIG. 3 is a cross-sectional view taken along an arrow line III-III in FIG. 2. In the following description, an X axis direction in FIG. 1 is a second direction (left-right direction) of the module device 1, a Y axis direction is a third direction (front-rear direction) of the module device 1, and a Z axis direction is a first direction (up-down direction) of the module device 1. In the description, a +X axis direction is a rightward direction, a −X axis direction is a leftward direction, a +Y axis direction is a rearward direction, a −Y axis direction is a forward direction, a +Z axis direction is an upward direction, and a −Z axis direction is a downward direction in FIG. 1.

As illustrated in FIG. 1 to FIG. 3, the module device 1 includes an electronic module 10 and a housing 2 on which the electronic module 10 is mounted. The housing 2 may be made of, for example, a cooling plate. Thus, the electronic module 10 can be cooled. The number of electronic modules included in the module device 1 may be one or two or more. The electronic module 10 may be mounted on a module substrate (not illustrated) instead of the housing 2.

As illustrated in FIG. 2 and FIG. 3, the electronic module 10 includes the case 11, a fixing member 12, and an electronic device 20.

The case 11 includes an accommodation space 11a at the center portion in the second direction (left-right direction), and the electronic device 20 is accommodated inside the accommodation space 11a. The case 11 is fixed to the housing 2 by the fixing member 12. The fixing member 12 may be, for example, a screw. The material of the case 11 may be metal.

As illustrated in FIG. 3, the electronic device 20 includes an electronic element 21, a substrate 30A, a metal plate 22, and a heat sink 23 in this order from the top.

The electronic element 21 in the present embodiment is configured by a laser diode or the like capable of emitting a laser, and the electronic device 20 emits the laser emitted from the electronic element 21 toward the outside.

In the electronic device 20, heat generated when the electronic element 21 is operated is conducted to the heat sink 23 via the substrate 30A and the metal plate 22, and is dissipated by the heat sink 23. Therefore, a high heat dissipation performance is required in the substrate 30A. A part of the heat conducted to the heat sink 23 is conducted to the housing 2 configured by the cooling plate via the case 11 and is dissipated in the housing 2.

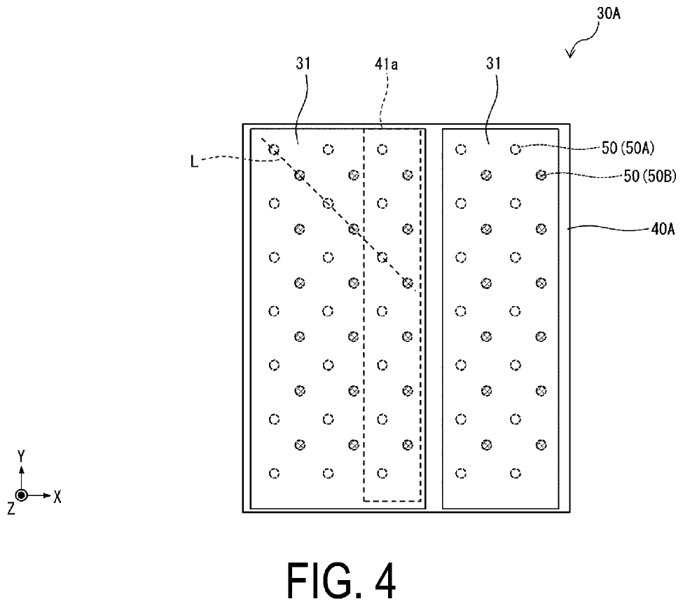

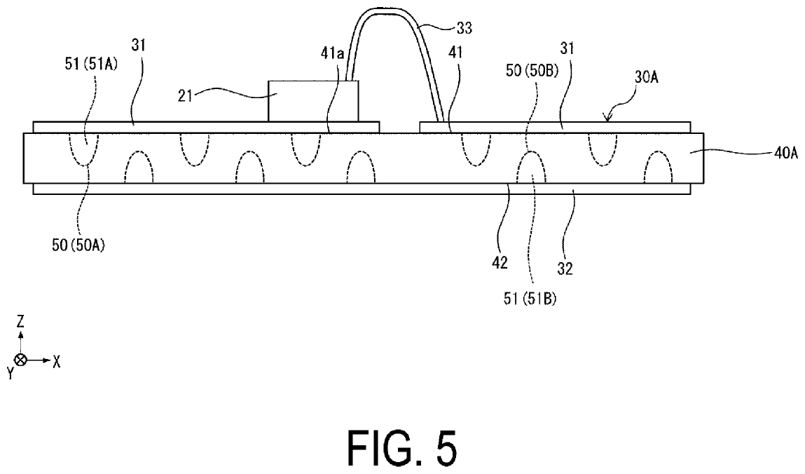

The substrate 30A is an electronic element mounting substrate for mounting the electronic element 21. The substrate 30A may be used for mounting heat-generating components other than the electronic elements. FIG. 4 is a top view of the substrate 30A. In FIG. 4, for convenience of description, an electronic element mounting portion 41a and a recessed portion 50, which will be described later, are indicated by dotted lines, and the recessed portion 50 formed in a second surface 42 is hatched. FIG. 5 is a view of the substrate 30A and the electronic element 21 viewed from the third direction (front-rear direction). In FIG. 5, the recessed portion 50 is indicated by a dashed line.

As illustrated in FIG. 4 and FIG. 5, the substrate 30A includes a base 40A, a metal member 51, a first electrical conductor film layer 31, and a second electrical conductor film layer 32.

The base 40A may be made of a single layer or a plurality of layers. As illustrated in FIG. 5, the base 40A in the present embodiment is a single insulation layer. The base 40A includes a first surface 41 on which the electronic element 21 is mounted, the second surface 42 located on the opposite side of the first surface 41, and the recessed portion 50. In the following description, for distinction, the recessed portion 50 having an opening in the first surface 41 may be referred to as a first recessed portion 50A, and the recessed portion 50 having an opening in the second surface 42 may be referred to as a second recessed portion 50B. The first surface 41 and the second surface 42 face each other. As illustrated in FIG. 4, the first surface 41 includes an electronic element mounting portion 41a on which the electronic element 21 is mounted at the center portion in the second direction.

The shape of the base 40A when the base 40A is viewed in a plan view is not particularly limited, and may be, for example, a rectangular shape, a circular shape, or the like. The base 40A in the present embodiment has a rectangular shape in a plan view. In this specification, the term “flat” or “planar” does not require being strictly flat or strictly planar.

The base 40A may have insulation. In this case, the base 40A may be made of, for example, a ceramic such as an aluminum nitride-based sintered body, an aluminum oxide-based sintered body (alumina ceramic), a silicon nitride-based sintered body, a mullite-based sintered body, or a glass ceramic sintered body. When the material of the base 40A is an aluminum nitride-based sintered body, the base 40A contains aluminum nitride as a main component. In this case, when the mass of the base 40A is taken as 100 mass %, the base 40A contains 80 mass % or more of aluminum nitride. The base 40A may contain 95 mass % or more of aluminum nitride. As such, the coefficient of thermal conductivity of the base 40A can be easily set to 170 W/mK or more, and thus the heat dissipation property of the base 40A can be increased.

The base 40A includes at least one recessed portion 50 in each of the first surface 41 and the second surface 42. In the present embodiment, the base 40A includes a plurality of recessed portions 50 in each of the first surface 41 and the second surface 42.

The recessed portion 50 may have a cavity structure. The opening portion of the recessed portion 50 may have a circular shape when the substrate 30A is viewed in a plan view from the first direction. The recessed portion 50 has a bottom.

When the base 40A includes the plurality of recessed portions 50 on each of the first surface 41 and the second surface 42, the arrangement method of the plurality of recessed portions 50 is not particularly limited. For example, as illustrated in FIG. 4, the plurality of recessed portions 50 may be arranged so that four adjacent recessed portions 50 are located at the vertices of a rectangle on each of the first surface 41 and the second surface 42. In other words, the plurality of recessed portions 50 may be arranged at lattice-shaped positions on each of the first surface 41 and the second surface 42. As such, when the substrate 30A is viewed in a plan view, the plurality of recessed portions 50 are evenly arranged, and thus variation in heat dissipation performance of the substrate 30A is less likely to occur.

As illustrated in FIG. 5, the first recessed portion 50A provided in the first surface 41 may become narrower as the distance from the first surface 41 increases in a cross section cut along a plane parallel to the first direction (that is, the up-down direction) orthogonal to the first surface 41 and the second surface 42. In other words, in a cross section taken along a plane parallel to the first direction, the first recessed portion 50A may have a smaller width in the second direction as the distance from the first surface 41 on which the first recessed portion 50A is provided increases. As illustrated in FIG. 5, the shape of the first recessed portion 50A may be a curved shape that is convex from the first surface 41 toward the second surface 42 in the cross section cut in the first direction. For example, the cross-sectional shape of the first recessed portion 50A taken along a plane parallel to the first direction may be an elliptical hemispherical shape.

As illustrated in FIG. 5, the second recessed portion 50B provided in the second surface 42 may become narrower as the distance from the second surface 42 increases in a cross section cut along a plane parallel to the first direction. In other words, in a cross section cut along a plane parallel to the first direction, the second recessed portion 50B may have a smaller width in the second direction as the distance from the second surface 42 on which the second recessed portion 50B is provided increases. As illustrated in FIG. 5, the shape of the second recessed portion 50B may be a curved shape that is convex from the second surface 42 toward the first surface 41 in the cross section cut in the first direction.

The recessed portion 50 can be formed by performing blast processing on the first surface 41 or the second surface 42. By forming the recessed portion 50 by blast processing, the inner surface of the recessed portion 50 can be formed into a curved shape as illustrated in FIG. 5.

In the present embodiment, the opening areas of the plurality of recessed portions 50 when the base 40A is viewed in a plan view are the same, but no such limitation is intended, and the opening areas of the plurality of recessed portions 50 may be different from each other. An example in which the opening areas of the plurality of recessed portions 50 are not the same will be described in a second embodiment. In the present embodiment, the depths of the plurality of recessed portions 50 are the same, but no such limitation is intended, and the depths of the plurality of recessed portions 50 may be different from each other.

In the substrate 30A of the present disclosure, the shape of the recessed portion 50 is not limited to the above-described shape as long as the recessed portion 50 is formed in each of the first surface 41 and the second surface 42. The shape of the recessed portion 50 may be, for example, a cylindrical shape.

The inside of the recessed portion 50 is filled with the metal member 51 having the coefficient of thermal conductivity higher than the coefficient of thermal conductivity of the base 40A. The metal member 51 is not particularly limited as long as it has the coefficient of thermal conductivity higher than that of the base 40A. For example, when the material of the base 40A is an aluminum nitride-based sintered body, the metal member 51 may be made of copper, copper-tungsten, copper-molybdenum, aluminum or the like. Since the inside of the recessed portion 50 is filled with the metal member 51, the thermal conductivity of the substrate 30A can be improved. A plating method such as an electroplating method or a metallization method can be used to fill the recessed portion 50 with the metal member 51. In the following description, for distinction, the metal member 51 located inside the first recessed portion 50A may be referred to as a first metal member 51A, and the metal member 51 located inside the second recessed portion 50B may be referred to as a second metal member 51B.

In the base 40A, the first recessed portion 50A formed in the first surface 41 and the second recessed portion 50B formed in the second surface 42 may be alternately arranged in at least one direction perpendicular to the first direction when viewed in a plan perspective. In the base 40A of the present embodiment, the center of the opening of the first recessed portion 50A and the center of the opening of the second recessed portion 50B are alternately arranged on a straight line L illustrated in FIG. 4. With the above-described configuration, since the plurality of recessed portions 50 are evenly arranged on the first surface 41 and the second surface 42, variation in the heat dissipation performance of the entire base 40A is less likely to occur. With the above-described configuration, when the substrate 30A is viewed in a plan perspective, the first recessed portion 50A provided in the first surface 41 can be provided in a region which does not overlap the second recessed portion 50B provided in the second surface 42. This can avoid an electrical connection between the first electrical conductor film layer 31 and the second electrical conductor film layer 32. In this specification, the term “perpendicular” does not require being strictly perpendicular.

The base 40A may have at least one set of recessed portions 50 in which a part of the first recessed portion 50A overlaps the second recessed portion 50B when viewed in a plan perspective from the direction perpendicular to the first direction. For example, as illustrated in FIG. 5, the configuration may be achieved by forming the first recessed portion 50A formed in the first surface 41 to be deeper than the center of the base 40A in the first direction, and forming the second recessed portion 50B formed in the second surface 42 to be deeper than the center of the base 40A in the first direction. According to this configuration, the coefficient of thermal conductivity of the substrate 30A can be increased because the volume of the recessed portion 50 formed in the base 40A can be increased.

In the substrate 30A of one aspect of the present disclosure, thin film layers (not illustrated) may be provided on the surface of the recessed portion 50, the surface of the first surface 41, and the surface of the second surface 42. The thin film layer may be composed of, for example, tantalum nitride, nickel-chromium, nickel-chromium-silicon, tungsten-silicon, molybdenum-silicon, tungsten, molybdenum, titanium, chromium, or the like. The thin film layer can be formed by a formation technique such as a vapor deposition method, an ion plating method, or a sputtering method. Since the thin film layer is formed on the surface of the recessed portion 50, the surface of the first surface 41, and the surface of the second surface 42, bonding between the inner surface of the recessed portion 50 and the metal member 51, bonding between the first surface 41 and the first electrical conductor film layer 31, bonding between the metal member 51 and the first electrical conductor film layer 31, bonding between the second surface 42 and the second electrical conductor film layer 32, and bonding between the metal member 51 and the second electrical conductor film layer 32 can be improved.

As illustrated in FIG. 5, the first electrical conductor film layer 31 is located on the first surface 41 of the base 40A. The first electrical conductor film layer 31 is connected to the first metal member 51A filled in the first recessed portion 50A. As illustrated in FIG. 5, the first electrical conductor film layer 31 is connected to each of the first metal members 51A filled in the plurality of first recessed portions 50A provided in the first surface 41. The first electrical conductor film layer 31 is made of a material having excellent electric conductivity such as copper. The first electrical conductor film layer 31 is formed in two separate regions on the first surface 41. The electronic element 21 is mounted on one first electrical conductor film layer 31. The other first electrical conductor film layer 31 is used as a connecting portion of a connecting member 33 such as a bonding wire, and electrically connects the electronic element 21 to a wiring conductor of a wiring substrate (not illustrated). As will be described later, since the first electrical conductor film layer 31 is made of a thin film, in this specification, “the electronic element 21 is mounted on the first electrical conductor film layer 31” is described as a synonym of “the electronic element 21 is mounted on the electronic element mounting portion 41a of the first surface 41”.

The first electrical conductor film layer 31 is formed on the first surface 41 and has the coefficient of thermal conductivity higher than the coefficient of thermal conductivity of the base 40A. The first electrical conductor film layer 31 is not particularly limited as long as it has the coefficient of thermal conductivity higher than that of the base 40A. For example, when the material of the base 40A is an aluminum nitride-based sintered body, the material may be copper, copper-tungsten, copper-molybdenum, aluminum, or the like. Since the first electrical conductor film layer 31 is formed on the first surface 41, the thermal conductivity of the substrate 30A can be improved. The first electrical conductor film layer 31 can be formed on the first surface 41 by a plating method such as an electroplating method or a metallization method. As described above, a thin film layer (not illustrated) may be provided on the surface of the first surface 41. When the first electrical conductor film layer 31 and the metal member 51 are made of the same material, for example, when the first electrical conductor film layer 31 and the metal member 51 are made of copper, heat can be favorably transferred from the first electrical conductor film layer 31 to the metal member 51. The electronic element 21 is fixed to one first electrical conductor film layer 31 by a bonding material such as In or Au—Sn, and then the electrode of the electronic element 21 and the other first electrical conductor film layer 31 are electrically connected to each other via the connecting member 33 such as a bonding wire, whereby the electronic element 21 is mounted on the substrate 30A.

A plating layer may be formed on the upper surface of the first electrical conductor film layer 31. The plating layer may be made of a metal having excellent corrosion resistance and connectivity with the connecting member 33, such as nickel, copper, gold, or silver. The plating layer may be formed by, for example, sequentially depositing a nickel plating layer having a thickness of 0.5 to 5 μm and a gold plating layer having a thickness of 0.1 to 3 μm. As such, the possibility of corrosion of the first electrical conductor film layer 31 can be reduced while the fixing between the first electrical conductor film layer 31 and the electronic element 21 and the bonding between the first electrical conductor film layer 31 and the connecting member 33 can be strengthened.

The second electrical conductor film layer 32 is located on the second surface 42 of the base 40A. The second electrical conductor film layer 32 may have the same material and configuration as the first electrical conductor film layer 31. The second electrical conductor film layer 32 is used for bonding with the metal plate 22. When the second electrical conductor film layer 32 and the metal member 51 are formed of the same material, for example, when the second electrical conductor film layer 32 and the metal member 51 are made of copper, heat can be favorably transferred from the metal member 51 to the second electrical conductor film layer 32.

Here, when the sum of the volume of the first metal members 51A filled in the plurality of first recessed portions 50A provided in the first surface 41 and the volume of the first electrical conductor film layer 31 is significantly different from the sum of the volume of the second metal members 51B filled in the plurality of second recessed portions 50B provided in the second surface 42 and the volume of the second electrical conductor film layer 32, the base 40A warps due to the difference between the coefficient of thermal expansion of the base 40A and the coefficient of thermal expansion of the metal member 51. Therefore, in the substrate 30A, the sum of the volume of the first metal members 51A filled in the plurality of first recessed portions 50A provided in the first surface 41 and the volume of the first electrical conductor film layer 31 may be set to 90 vol % or more and 110 vol % or less of the sum of the volume of the second metal members 51B filled in the plurality of second recessed portions 50B provided in the second surface 42 and the volume of the second electrical conductor film layer 32. Thus, the amount of warp of the base 40A can be reduced. When the substrate 30A does not include both the first electrical conductor film layer 31 and the second electrical conductor film layer 32, the sum of the volume of the first metal members 51A filled in the plurality of first recessed portions 50A provided in the first surface 41 may be set to 90 vol % or more and 110 vol % or less of the sum of the volume of the second metal members 51B filled in the plurality of second recessed portions 50B provided in the second surface 42.

As described above, in the substrate 30A of the present embodiment, the base 40A includes the plurality of recessed portions 50 filled with the metal members 51 in the first surface 41 and the second surface 42. Thus, the volume of the metal member 51 included in the base 40A can be increased as compared to a base in which the recessed portion 50 is formed only in one of the first surface 41 and the second surface 42. As a result, the coefficient of thermal conductivity of the substrate 30A can be increased. The recessed portion 50 may be formed in the first surface 41 on which the electronic element 21 is mounted. The width of the recessed portion 50 in the front-rear direction decreases as the distance from the first surface 41 increases in a cross section taken along a plane parallel to the up-down direction.

In the substrate 30A in the present embodiment, the recessed portion 50 is formed in the first surface 41 on which the electronic element 21 is mounted and the second surface 42. The width of the recessed portion 50 in the second direction decreases as the distance from the first surface 41 or the second surface 42 increases in a cross section taken along a plane parallel to the first direction. In other words, the diameter of the recessed portion 50 decreases as the distance from the first surface 41 or the second surface 42 increases in a cross section taken along a plane parallel to the first direction. Thus, for example, the surface area of the recessed portion 50 can be increased as compared to the case where the recessed portion 50 has a rectangular parallelepiped shape. As a result, heat is easily transferred from the metal member 51 on the first surface 41 side to the base 40A, and from the base 40A to the metal member 51 on the second surface 42 side. As such, the coefficient of thermal conductivity of the substrate 30A can be increased.

As illustrated in FIG. 5, the shape of the recessed portion 50 is a curved shape that is convex from the surface on which the recessed portion 50 is formed toward the surface of the opposite side in the cross section cut in the first direction. Thus, when a load in the first direction is applied to the substrate 30A, stresses applied to the surface on which the recessed portion 50 is formed can be dispersed. As a result, the likelihood of damage to the substrate 30A can be reduced.

In the substrate 30A, the first metal member 51A filled in the first recessed portion 50A formed on the first surface 41 side is in contact with the first electrical conductor film layer 31 as illustrated in FIG. 5. Thus, heat conducted from the electronic element 21 to the first electrical conductor film layer 31 is easily conducted to the first metal member 51A. As illustrated in FIG. 5, the second metal member 51B filled in the second recessed portion 50B formed on the second surface 42 side is in contact with the second electrical conductor film layer 32. Thus, heat transferred to the base 40A is easily conducted to the second electrical conductor film layer 32 via the second metal member 51B. Therefore, the thermal conductivity of the substrate 30A can be improved.

Although the laser diode is mounted as the electronic element 21 on the substrate 30A in the present embodiment, the electronic element mounted on the substrate 30A is not limited to the laser diode. For example, the electronic element mounted on the substrate 30A may be a semiconductor element such as an IC-chip or an LSI-chip, or a piezoelectric element such as a crystal resonator or a piezoelectric oscillator.

### Second Embodiment

Another embodiment of the present disclosure will be described below. For convenience of description, members having the same functions as those of the members described in the above-described embodiment are denoted by the same reference signs, and description thereof is not repeated.

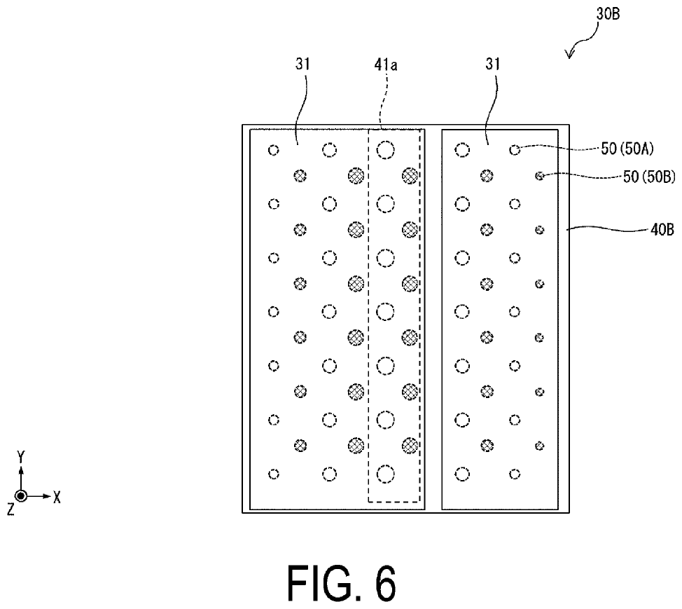

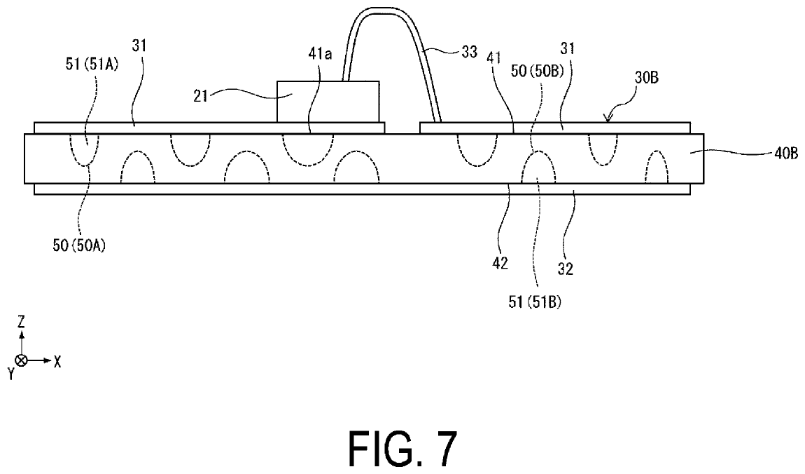

FIG. 6 is a top view of a substrate 30B in the present embodiment. In FIG. 6, for convenience of description, the electronic element mounting portion 41a and the recessed portion 50 are indicated by dotted lines, and the recessed portion 50 formed in the second surface 42 is hatched. FIG. 7 is a view of the substrate 30B and the electronic element 21 viewed from the third direction (front-rear direction). In FIG. 7, the recessed portion 50 is indicated by a dashed line.

As illustrated in FIG. 6 and FIG. 7, the substrate 30B includes a base 40B instead of the base 40A in the first embodiment.

In the base 40B, the plurality of recessed portions 50 filled with the metal members 51 are formed in each of the first surface 41 and the second surface 42. In the base 40B, the opening diameter of the recessed portion 50 decreases as the positions at which the recessed portions 50 are formed in the second direction go outward from the center portion. Thus, in the substrate 30B, the opening area of the recessed portion 50 increases from the outer side in the second direction toward the electronic element mounting portion 41a when viewed in a plan view. In other words, when viewed in a plan view, the opening area of the recessed portion 50 provided in the electronic element mounting portion 41a or the region close to the electronic element mounting portion 41a is larger than the opening area of the recessed portion 50 provided in the region far from the electronic element mounting portion 41a.

With the above-described configuration, in the base 40B, heat is easily transferred from the first surface 41 to the inside of the base 40B and also easily transferred from the inside of the base 40B to the second surface 42 in the electronic element mounting portion 41a in which the recessed portion 50 having a large opening area is formed or in a region close to the electronic element mounting portion 41a. In other words, in the substrate 30B, the coefficient of thermal conductivity in the vicinity of the electronic element mounting portion 41a is higher than that in the outer portion. As such, the heat conducted from the electronic element 21 is easily transferred to the metal plate 22 efficiently, and the temperature of the electronic element 21 is easily lowered. In a case where the electronic element 21 is mounted only on the center portion of the first surface 41 of the substrate 30B in the third direction due to the size or shape of the electronic element 21, in this case, in the base 40B, the opening diameter of the recessed portion 50 may decrease from the center portion of the first surface 41 in the third direction toward the outer side.

### Third Embodiment

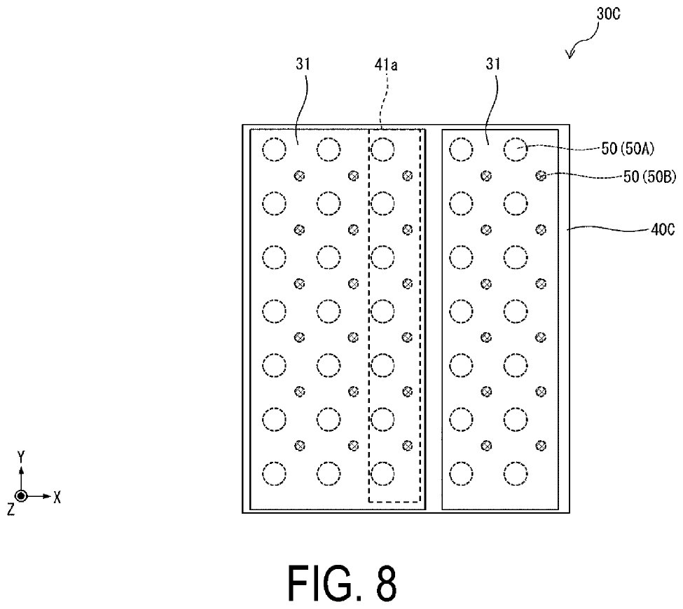

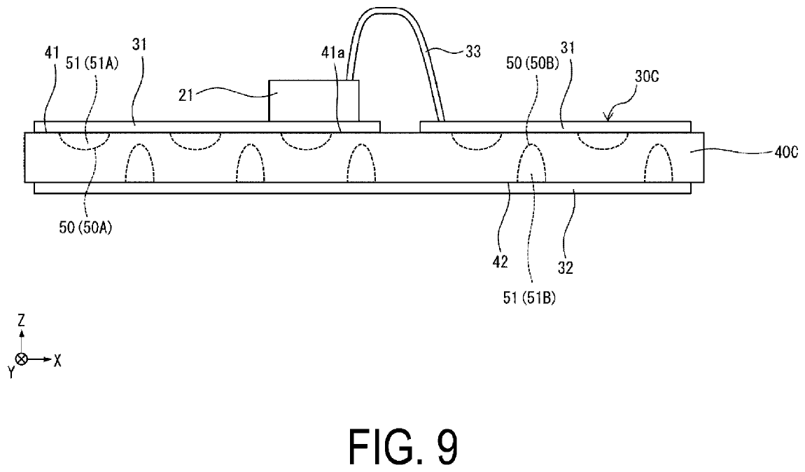

Another embodiment of the present disclosure will be described below. FIG. 8 is a top view of a substrate 30C in the present embodiment. In FIG. 8, for convenience of description, the recessed portion 50 formed in the second surface 42 is indicated by hatching. FIG. 9 is a view of the substrate 30C and the electronic element 21 viewed from the third direction. In FIG. 9, the recessed portion 50 is indicated by a dashed line.

As illustrated in FIG. 8 and FIG. 9, the substrate 30C includes a base 40C instead of the base 40A in the first embodiment.

The base 40C includes a plurality of recessed portions 50 filled with the metal members 51 in the first surface 41 and the second surface 42. In the base 40C of the present embodiment, as illustrated in FIG. 9, the depth of the second recessed portion 50B provided in the second surface 42 located at a position farther from the electronic element 21, which is a heat generation source, than the first surface 41 is deeper than the depth of the first recessed portion 50A provided in the first surface. Thus, the distance between the first recessed portion 50A provided in the first surface 41 and the second recessed portion 50B provided in the second surface 42 can be reduced. This facilitates heat transfer from the first metal member 51A filled in the first recessed portion 50A to the second metal member 51B filled in the second recessed portion 50B. As a result, the heat dissipation performance of the substrate 30C can be improved. The depth of the first recessed portion 50A indicates the distance from the first surface 41 to the bottom portion of the first recessed portion 50A, and the depth of the second recessed portion 50B indicates the distance in the Z axis direction from the second surface 42 to the bottom portion of the second recessed portion 50B.

As described in the first embodiment, when the sum of the volume of the first metal members 51A filled in the plurality of first recessed portions 50A provided in the first surface 41 and the volume of the first electrical conductor film layer 31 is significantly different from the sum of the volume of the second metal members 51B filled in the plurality of second recessed portions 50B provided in the second surface 42 and the volume of the second electrical conductor film layer 32, the base 40C warps. Therefore, as illustrated in FIG. 9, the base 40C in the present embodiment may be configured such that the opening area of the second recessed portion 50B formed in the second surface 42 is smaller than the opening area of the first recessed portion 50A formed in the first surface 41. As such, the volume of the first recessed portion 50A formed in the first surface 41 can be made to be significantly different from the volume of the second recessed portion 50B formed in the second surface 42. Thus, the amount of warp of the base 40C can be reduced.

### Fourth Embodiment

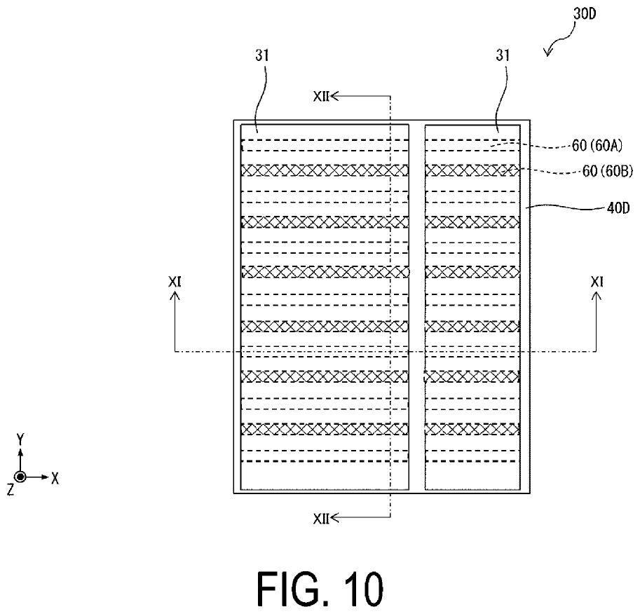

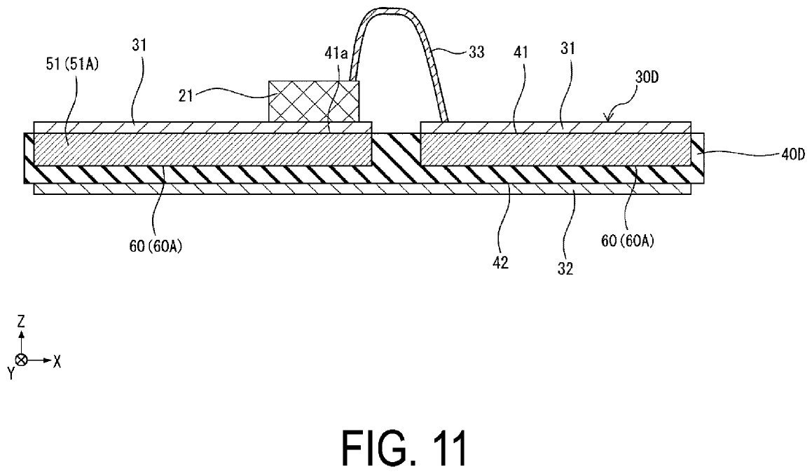

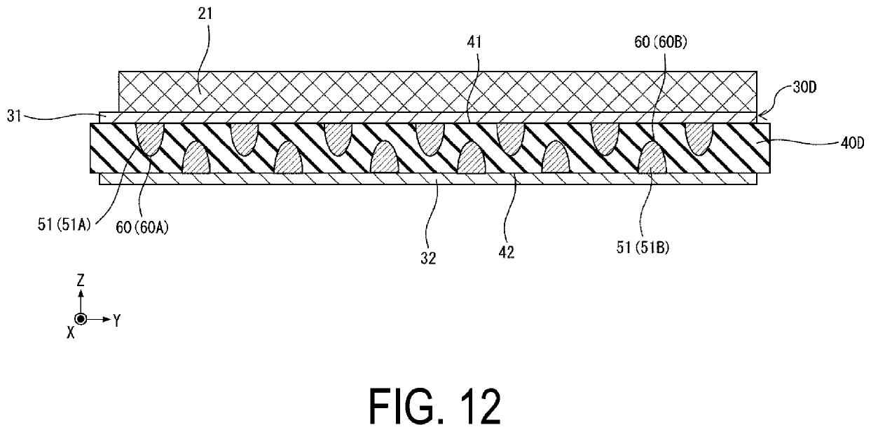

Another embodiment of the present disclosure will be described below. FIG. 10 is a top view of a substrate 30D in the present embodiment. FIG. 11 is a cross-sectional view taken along an arrow line XI-XI in FIG. 10. FIG. 12 is a cross-sectional view taken along an arrow line XII-XII in FIG. 10.

As illustrated in FIG. 10 to FIG. 12, the substrate 30D includes a base 40D instead of the base 40A in the first embodiment.

In the base 40D, a plurality of recessed portions 60 filled with the metal members 51 are formed in each of the first surface 41 and the second surface 42. As illustrated in FIG. 10 and FIG. 11, the recessed portion 60 is a slit extending in the second direction perpendicular to the first direction. As illustrated in FIG. 10, the recessed portion 60 may be provided in a region overlapping the first electrical conductor film layer 31 when the base 40D is viewed in a plan perspective. The recessed portion 60 in the present embodiment is formed so that the length thereof in the second direction is the same as the length in the second direction of the first electrical conductor film layer 31, but may be shorter than the length in the second direction of the first electrical conductor film layer 31. In the following description, for distinction, the recessed portion 60 having an opening in the first surface 41 may be referred to as a first recessed portion 60A, and the recessed portion 60 having an opening in the second surface 42 may be referred to as a second recessed portion 60B.

As illustrated in FIG. 12, the first recessed portion 60A provided in the first surface 41 may have a shape in which the length in the third direction decreases as the distance from the first surface 41 increases in a cross section taken along a plane perpendicular to the second direction. Thus, for example, the surface area of the first recessed portion 60A can be increased compared to a case where the shape of the cross section cut along the plane perpendicular to the second direction is a rectangular shape. As a result, heat transfer from the first metal member 51A to the base 40D is facilitated. As such, the coefficient of thermal conductivity of the substrate 30D can be increased.

The second recessed portion 60B provided in the second surface 42 may have a cross-sectional shape taken along a plane perpendicular to the second direction such that the length in the third direction decreases as the distance from the second surface 42 increases. The slit can be formed by performing blast processing on the first surface 41 and the second surface 42 of the base 40D in the same and/or similar manner as in the above embodiment.

In the base 40D, as illustrated in FIG. 10, the first recessed portion 60A provided in the first surface 41 may be provided in a region that does not overlap the second recessed portion 60B provided in the second surface 42 when viewed in a plan perspective. This can avoid an electrical connection between the first electrical conductor film layer 31 and the second electrical conductor film layer 32.

The recessed portion 60 in the present embodiment is a slit extending in the second direction (left-right direction), but is not limited to this. The recessed portion 60 may be a slit extending in any direction as long as the direction is perpendicular to the up-down direction. For example, the recessed portion 60 may be a slit extending in the third direction (front-rear direction).

In the substrate 30D of the present disclosure, the shape of the recessed portion 60 is not limited to the above-described shape as long as the recessed portion 60 is formed in each of the first surface 41 and the second surface 42. The shape of the recessed portion 60 may be, for example, a rectangular shape or a triangular shape in a cross section perpendicular to the longitudinal direction.

In the substrate 30D of the present embodiment, the recessed portions formed in the first surface 41 and the second surface 42 are slits, but are not limited thereto. In the substrate of one aspect of the present disclosure, the recessed portion 50 having the cavity structure may be formed on one of the first surface 41 and the second surface 42, and the recessed portion 60 having the slit structure may be formed on the other surface.

### Fifth Embodiment

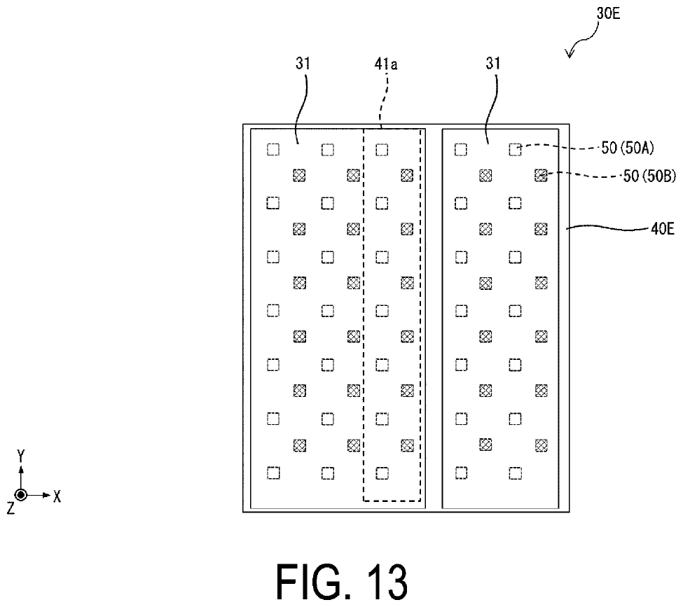

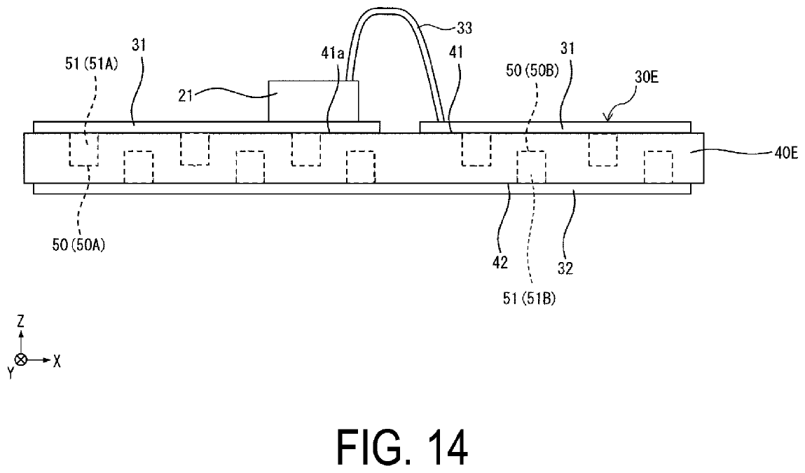

Another embodiment of the present disclosure will be described below. FIG. 13 is a top view of a substrate 30E according to the present embodiment. In FIG. 13, for convenience of description, the electronic element mounting portion 41a and the recessed portion 50 are indicated by dotted lines, and the recessed portion 50 formed in the second surface 42 is hatched. FIG. 14 is a view of the substrate 30E and the electronic element 21 viewed from the third direction (front-rear direction). In FIG. 14, the recessed portion 50 is indicated by a dashed line.

As illustrated in FIG. 10 to FIG. 12, the substrate 30E includes a base 40E instead of the base 40A in the first embodiment.

In the base 40E, the plurality of recessed portions 50 filled with the metal members 51 are formed in each of the first surface 41 and the second surface 42. As illustrated in FIG. 13 and FIG. 14, the recessed portion 50 has a rectangular parallelepiped shape extending along the first direction. The inside of the recessed portion 50 is filled with the metal members 51 having the coefficient of thermal conductivity higher than the coefficient of thermal conductivity of the base 40E.

With the above-described configuration, in the substrate 30E of the present embodiment, the base 40E includes the plurality of recessed portions 50 filled with the metal members 51 in the first surface 41 and the second surface 42. Thus, the volume of the metal member 51 included in the base 40E can be increased as compared to a base in which the recessed portion 50 is formed only in one of the first surface 41 and the second surface 42. As a result, the coefficient of thermal conductivity of the substrate 30E can be increased.

In the present embodiment, the opening areas of the plurality of recessed portions 50 when the base 40E are viewed in a plan view are the same, but no such limitation is intended, and the opening areas of the plurality of recessed portions 50 may be different from each other. In the present embodiment, the depths of the plurality of recessed portions 50 are the same, but no such limitation is intended, and the depths of the plurality of recessed portions 50 may be different from each other.

A substrate according to a first aspect of the present disclosure includes a base including a first surface, a second surface located on an opposite side of the first surface, at least one first recessed portion opening to the first surface, and at least one second recessed portion opening to the second surface, a first metal member located inside the at least one first recessed portion, and a second metal member located inside the at least one second recessed portion, in which the coefficient of thermal conductivity of the first metal member and the coefficient of thermal conductivity of the second metal member are higher than the coefficient of thermal conductivity of the base.

In the substrate according to a second aspect of the present disclosure, in the first aspect, the base may include a plurality of first recessed portions and a plurality of second recessed portions.

In the substrate according to a third aspect of the present disclosure, in the first or second aspect, an opening portion of at least one of the at least one first recessed portion or the at least one second recessed portion may have a circular shape in a plan view.

In the substrate according to a fourth aspect of the present disclosure, in any one of the first to third aspects, the base may include a plurality of first recessed portions and a plurality of second recessed portions, the plurality of first recessed portions may be arranged in a lattice shape in the first surface, and the plurality of second recessed portions may be arranged in a lattice shape in the second surface.

In the substrate according to a fifth aspect of the present disclosure, in the fourth aspect, the at least one first recessed portion and the at least one second recessed portion may be alternately arranged in at least one direction perpendicular to a first direction orthogonal to the first surface and the second surface when the substrate is viewed in a plan perspective.

In the substrate according to a sixth aspect of the present disclosure, in any one of the first to fifth aspects, the substrate may be configured such that the at least one first recessed portion does not overlap the at least one second recessed portion when the substrate is viewed in a plan perspective.

In the substrate according to a seventh aspect of the present disclosure, in any one of the first to sixth aspects, a part of the at least one first recessed portion may overlap with the at least one second recessed portion when viewed in perspective in a direction perpendicular to a first direction orthogonal to the first surface and the second surface.

In the substrate according to an eighth aspect of the present disclosure, in any one of the first to seventh aspects, a sum of volume of the first metal members filled in insides of the at least one first recessed portion may be 90 vol % or more and 110 vol % or less of a sum of volume of the second metal members filled in insides of the at least one second recessed portion.

The substrate according to a ninth aspect of the present disclosure may further include, in any one of the first to seventh aspects, a first electrical conductor film layer located on the first surface and a second electrical conductor film layer located on the second surface, and a sum of a volume of the first metal member filled in an inside of the at least one first recessed portion and a volume of the first electrical conductor film layer may be 90 vol % or more and 110 vol % or less of a sum of a volume of the second metal member filled in an inside of the at least one second recessed portion and a volume of the second electrical conductor film layer.

In the substrate according to a tenth aspect of the present disclosure, in any one of the first to ninth aspects, in at least one cross section cut in a first direction orthogonal to the first surface and the second surface, a width of the at least one first recessed portion in a direction parallel to the first surface may decrease as a distance from the first surface increases, and a width of the at least one second recessed portion in a direction parallel to the first surface may decrease as a distance from the second surface increases.

In the substrate according to an eleventh aspect of the present disclosure, in the tenth aspect, a shape of the at least one first recessed portion and the at least one second recessed portion may be a curved shape from a surface of one of the first surface and the second surface in which the at least one first recessed portion or the at least one second recessed portion is provided toward a surface on an opposite side in at least one cross section cut in the first direction.

In the substrate according to a twelfth aspect of the present disclosure, in any one of the first to eleventh aspects, the base may include an electronic element mounting portion on the first surface, and an opening area of the at least one second recessed portion may be smaller than an opening area of the at least one first recessed portion.

In the substrate according to a thirteenth aspect of the present disclosure, in any one of the first to twelfth aspects, the base may include an electronic element mounting portion on the first surface, and a depth of the at least one second recessed portion may be deeper than a depth of the at least one first recessed portion.

In the substrate according to a fourteenth aspect of the present disclosure, in any one of the first and sixth to thirteenth aspects, at least one of the at least one first recessed portion or the at least one second recessed portion may be a slit extending in a second direction perpendicular to a first direction in which the first surface and the second surface face each other.

In the substrate according to a fifteenth aspect of the present disclosure, in the fourteenth aspect, the substrate may be configured such that the at least one first recessed portion does not overlap the at least one second recessed portion when the substrate is viewed in a plan perspective.

In an electronic device according to a sixteenth aspect of the present disclosure, an electronic element is mounted on the substrate according to any one of the first to fifteenth aspects.

In an electronic module according to a seventeenth aspect of the present disclosure, the electronic device according to the sixteenth aspect is accommodated in a case.

In a module device according to an eighteenth aspect of the present disclosure, the electronic module according to the seventeenth aspect is mounted on a module substrate or a housing.

The invention according to the present disclosure has been described above based on the various drawings and examples. However, the invention according to the present disclosure is not limited to each embodiment described above. That is, the invention according to the present disclosure can be modified in various ways within the scope illustrated in the present disclosure, and embodiments obtained by appropriately combining the technical means disclosed in different embodiments are also included within the technical scope of the invention according to the present disclosure. In other words, those skilled in the art can easily make various variations or modifications based on the present disclosure. Note that these variations or modifications are included within the scope of the present disclosure.

### REFERENCE SIGNS

1 Module device
2 Housing
10 Electronic module
11 Case
20 Electronic device
21 Electronic element
30A, 30B, 30C, 30D, 30E Substrate
31 First electrical conductor film layer
32 Second electrical conductor film layer
40A, 40B, 40C, 40D, 40E Base
41a Electronic element mounting portion
50, 60 Recessed portion
50A, 60A First recessed portion
50B, 60B Second recessed portion
51 Metal member
51A First metal member
51B Second metal member

1. A substrate comprising:
a base comprising a first surface, a second surface located on an opposite side of the first surface, at least one first recessed portion opening to the first surface, and at least one second recessed portion opening to the second surface;
a first metal member located inside the at least one first recessed portion; and
a second metal member located inside the at least one second recessed portion, wherein
a coefficient of thermal conductivity of the first metal member and a coefficient of thermal conductivity of the second metal member are higher than a coefficient of thermal conductivity of the base.

2. The substrate according to claim 1, wherein
the base comprises a plurality of first recessed portions and a plurality of second recessed portions.

3. The substrate according to claim 1, wherein
an opening portion of at least one of the at least one first recessed portion or the at least one second recessed portion has a circular shape in a plan view.

4. The substrate according to claim 1, wherein
the base comprises a plurality of first recessed portions and a plurality of second recessed portions,
the plurality of first recessed portions are arranged in a lattice shape in the first surface, and
the plurality of second recessed portions are arranged in a lattice shape in the second surface.

5. The substrate according to claim 4, wherein
the at least one first recessed portion and the at least one second recessed portion are alternately arranged in at least one direction perpendicular to a first direction orthogonal to the first surface and the second surface when the substrate is viewed in a plan perspective.

6. The substrate according to claim 1, wherein
the at least one first recessed portion does not overlap the at least one second recessed portion when the substrate is viewed in a plan perspective.

7. The substrate according to claim 1, wherein
in the base, a part of the at least one first recessed portion overlaps the at least one second recessed portion when viewed in perspective in a direction perpendicular to a first direction orthogonal to the first surface and the second surface.

8. The substrate according to claim 1, wherein
a sum of a volume of the first metal member filled in insides of the at least one first recessed portion is 90 vol % or more and 110 vol % or less of a sum of a volume of the second metal member filled in insides of the at least one second recessed portion.

9. The substrate according to claim 1, further comprising:
a first electrical conductor film layer located on the first surface; and
a second electrical conductor film layer located on the second surface, wherein
a sum of a volume of the first metal member filled in an inside of the at least one first recessed portion and a volume of the first electrical conductor film layer is 90 vol % or more and 110 vol % or less of a sum of a volume of the second metal member filled in an inside of the at least one second recessed portion and a volume of the second electrical conductor film layer.

10. The substrate according to claim 1, wherein
in at least one cross section cut in a first direction orthogonal to the first surface and the second surface, a width of the at least one first recessed portion in a direction parallel to the first surface decreases as a distance from the first surface increases, and a width of the at least one second recessed portion in a direction parallel to the first surface decreases as a distance from the second surface increases.

11. The substrate according to claim 10, wherein
in at least one cross section cut in the first direction, a shape of the at least one first recessed portion and the at least one second recessed portion is a curved shape from a surface of one of the first surface and the second surface in which the at least one first recessed portion or the at least one second recessed portion is provided toward a surface on an opposite side.

12. The substrate according to claim 1, wherein
the base comprises an electronic element mounting portion on the first surface, and
an opening area of the at least one second recessed portion is smaller than an opening area of the at least one first recessed portion.

13. The substrate according to claim 1, wherein
the base comprises an electronic element mounting portion on the first surface, and
a depth of the at least one second recessed portion is deeper than a depth of the at least one first recessed portion.

14. The substrate according to claim 1, wherein
at least one of the at least one first recessed portion or the at least one second recessed portion is a slit extending in a second direction perpendicular to a first direction in which the first surface and the second surface face each other.

15. The substrate according to claim 14, wherein
the at least one first recessed portion does not overlap the at least one second recessed portion when the substrate is viewed in a plan perspective.

16. An electronic device, wherein
an electronic element is mounted on the substrate according to claim 1.

17. An electronic module, wherein
the electronic device according to claim 16 is accommodated in a case.

18. A module device, wherein
the electronic module according to claim 17 is mounted on a module substrate or a housing.
